(19) United States
(12) Patent Application Publication
(10) Pub. No.: US 2026/0056478 A1
(43) Pub. Date: Feb. 26, 2026

(54) METHOD OF CONTROLLING SEMICONDUCTOR PROCESS

(71) Applicant: SAMSUNG ELECTRONICS CO., LTD., Suwon-si (KR)

(72) Inventors: Dooho KANG, Suwon-si (KR); Euiseok KUM, Suwon-si (KR); Sungchai KIM, Suwon-si (KR); Sungwon PARK, Suwon-si (KR); Gilwoo SONG, Suwon-si (KR)

(73) Assignee: SAMSUNG ELECTRONICS CO., LTD., Suwon-si (KR)

(21) Appl. No.: 19/054,297

(22) Filed: Feb. 14, 2025

(30) Foreign Application Priority Data
Aug. 23, 2024 (KR) 10-2024-0113758

(51) Int. Cl. G03F 7/00; G03F 9/00; H01L 23/544

(52) U.S. Cl. CPC G03F 7/706837; G03F 7/70633; G03F 7/70683; G03F 7/706841; G03F 9/7084; H01L 23/544; H01L 2223/54426

(57) ABSTRACT

Provided is a method of controlling a semiconductor process including obtaining measurement data by measuring an alignment mark of a wafer based on multiwavelength light emitted by a plurality of semiconductor process apparatuses, and obtaining a final position of the alignment mark by applying a current weight to the measurement data, measuring overlays of a plurality of measurement positions of the wafer by applying the current weight, generating overlay data by adding the measured overlays, obtaining first indices based on the measurement data and the overlay data and obtaining second indices based on the overlay data, determining at least one weight as a weight candidate group based on the first indices corresponding to each of the plurality of semiconductor process apparatuses, determining a weight from the weight candidate group as a final weight, and modifying the current weight to the final weight.

### CROSS-REFERENCE TO RELATED APPLICATION

This application claims priority to Korean Patent Application No. 10-2024-0113758 filed on Aug. 23, 2024 in the Korean Intellectual Property Office, the disclosure of which is incorporated herein by reference in its entirety.

### BACKGROUND

Embodiments of the present disclosure relate to a method of controlling a semiconductor process.

A semiconductor process may include a photo process, an etching process, a deposition process, or the like, to form a plurality of layers on a wafer, and a plurality of patterns may be formed in each of the plurality of layers. As a line width and a spacing of a plurality of patterns has become smaller, a photolithography process using light of a relatively short wavelength band, such as extreme ultraviolet (EUV) light, has been proposed. A photolithography process may be of transferring a pattern to a wafer by irradiating (emitting) light on a mask, and it may be important to form a pattern at a predetermined position on a wafer. An alignment mark may be used to control alignment of the mask and the wafer.

### SUMMARY

One or more embodiments provide a semiconductor process which may optimize a weight applied to multi-wavelength light to more accurately measure the position of alignment marks and improve dispersion of overlay.

According to an aspect of one or more embodiments, there is provided a method of controlling a semiconductor process, the method including obtaining measurement data by measuring an alignment mark of a wafer based on multiwavelength light emitted by a plurality of semiconductor process apparatuses, and obtaining a final position of the alignment mark by applying a current weight to the measurement data, performing a semiconductor process on the wafer by aligning a mask stage and a wafer stage based on the final position of the alignment mark, measuring overlays of a plurality of measurement positions of the wafer by applying the current weight to the multiwavelength light, and generating overlay data by adding the measured overlays, with respect to the plurality of semiconductor process apparatuses, obtaining first indices based on at least one of the measurement data and the overlay data, and obtaining second indices, different from the first indices, based on the overlay data, generating machine learning models corresponding to the first indices and the second indices based on the current weight, predicting the first indices corresponding to the plurality of semiconductor process apparatuses, respectively, for each of a plurality of weights configured to be applied to the multiwavelength light based on the machine learning models, determining at least one weight among the plurality of weights as a weight candidate group based on the first indices for each of the plurality of semiconductor process apparatuses, predicting second indices corresponding to the plurality of semiconductor process apparatuses, respectively, for the weight candidate group based on the machine learning models, determining a weight from the weight candidate group as a final weight based on the second indices for the plurality of semiconductor process apparatuses, respectively, and modifying the current weight to the final weight, wherein the first indices includes at least one of a distribution of overlay for the plurality of measurement positions of the wafer and an accuracy of the measurement data, and the second indices correspond to the distribution of overlay for the plurality of measurement positions of the wafer.

According to another aspect of one or more embodiments, there is provided a method of controlling a semiconductor process, the method including obtaining measurement data by measuring an alignment mark of a wafer based on multiwavelength light emitted by a plurality of semiconductor process apparatuses, and obtaining a final position of the alignment mark by applying a current weight to the measurement data, aligning a mask stage and a wafer stage based on the final position of the alignment mark and performing a semiconductor process on the wafer, measuring overlays of a plurality of measurement positions of the wafer by applying the current weight to the multiwavelength light, and generating overlay data by adding the measured overlays, with respect to the plurality of semiconductor process apparatuses, obtaining first indices based on at least one of the measurement data and the overlay data, and obtaining second indices, different from the first indices, based on the overlay data, obtaining first average indices, an average of the first indices, and second average indices, an average of the second indices, for each of the plurality of semiconductor process apparatuses based on the first indices and the second indices corresponding to the current weight, generating machine learning models corresponding to the first indices and the second indices based on the current weight, predicting first average indices corresponding to the plurality of semiconductor process apparatuses, respectively, for each of a plurality of weights configured to be applied to the multiwavelength light based on the machine learning models, determining at least one weight in which a first average index is outside of and less than a predetermined range of index or the same as the current weight among the plurality of weights as a weight candidate group, predicting second average indices for the plurality of semiconductor process apparatuses, respectively, for the weight candidate group based on the machine learning models, determining a weight in which a second average index is outside of the predetermined range of index and has the smallest value in the weight candidate group as a final weight, and modifying the current weight to the final weight.

According to yet another aspect of one or more embodiments, there is provided a method of controlling a semiconductor process, the method including obtaining measurement data by measuring an alignment mark of a wafer based on multiwavelength light in a plurality of semiconductor process apparatuses, and obtaining a final position of the alignment mark by applying a current weight to the measurement data, aligning a mask stage and a wafer stage based on the final position of the alignment mark and performing a semiconductor process on each of a plurality of unit regions of the wafer, measuring overlays of a plurality of measurement positions of the wafer by applying the current weight to the multiwavelength light, and generating overlay data by adding the measured overlays, with respect to the plurality of semiconductor process apparatuses, obtaining first indices corresponding to a distribution of overlays for the plurality of measurement positions of the wafer based on the overlay data, generating machine learning models corresponding to the first indices and an overlay based on the current weight, predicting first indices for the plurality of semiconductor process apparatuses, respectively, for each of a plurality of weights configured to be applied to the multiwavelength light based on the machine learning models, determining at least one weight among the plurality of weights as a weight candidate group based on the first indices for each of the plurality of semiconductor process apparatuses, predicting the overlay corresponding to the weight candidate group based on the machine learning models, classifying the overlays for the weight candidate group by unit region, determining a weight from the weight candidate group that is outside of and less than a predetermined range of index as a final weight with respect to each of the plurality of unit regions, and modifying the current weight to the final weight with respect to the unit region.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a semiconductor process apparatus according to one or more embodiments;

FIG. 2 is a diagram illustrating a wafer according to one or more embodiments;

FIG. 3 is an enlarged diagram illustrating region “A” illustrated in FIG. 2;

FIG. 4 is a diagram illustrating overlay caused by deformation of a shape of first structures according to one or more embodiments;

FIG. 5 is a flowchart illustrating a process of performing a semiconductor process apparatus according to one or more embodiments;

FIG. 6 is a diagram illustrating multiwavelength light according to one or more embodiments;

FIG. 7 is a flowchart illustrating a process of controlling a current weight according to one or more embodiments;

FIG. 8 is a diagram illustrating overlay data and indices in one or more embodiments;

FIGS. 9, 10, 11, 12, and 13 are diagrams illustrating a process of controlling a weight according to one or more embodiments;

FIGS. 14 and 15 are diagrams illustrating a process of determining a final weight of a unit region using a limit section according to one or more embodiments;

FIGS. 16 and 17 are diagrams illustrating a process of determining a final weight of a unit region using an overlay range according to one or more embodiments; and

FIGS. 18A, 18B, 18C, 18D, 18E, and 18F are diagrams illustrating overlay standard deviation derived from a wafer according to one or more embodiments.

### DETAILED DESCRIPTION

In the description below, embodiments of the present disclosure will be described as follows with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

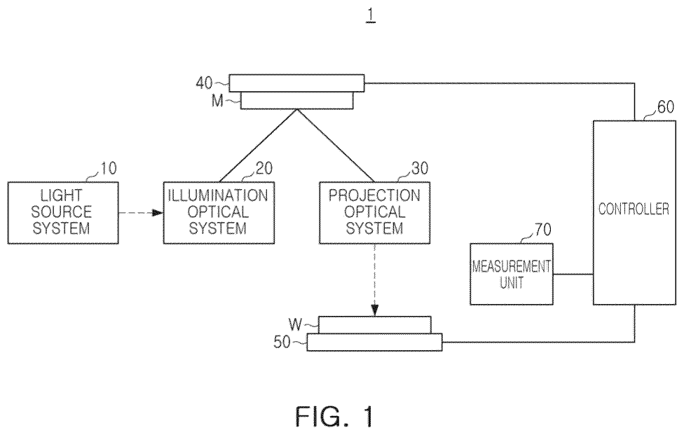

FIG. 1 is a diagram illustrating a semiconductor process apparatus according to one or more embodiments.

Referring to FIG. 1, a semiconductor process apparatus 1 according to one or more embodiments may be configured to perform a photolithography process, and may include a light source system 10, an illumination optical system 20, a projection optical system 30, a mask stage 40, a wafer stage 50, a controller 60, and a measurement unit 70.

The light source system 10 may generate and output extreme ultraviolet light having relatively high energy density within a wavelength band range of several nanometers to several tens of nanometers. In one or more embodiments, the light source system 10 may generate and output extreme ultraviolet light having relatively high energy density in a wavelength band of 13.5 nm. The light source system 10 may include a plasma-based light source, a synchrotron radiation light source, or the like.

The plasma-based light source may refer to a light source generating plasma and using light emitted by the plasma. For example, the light source system 10 may operate in a laser-produced plasma (LPP) mode in which a high-output laser is irradiated (emitted) to a droplet formed of one of materials such as, for example, tin, lithium, and xenon to generate plasma, or in a discharge-produced plasma (DPP) mode, or in a master oscillator power amplifier (MOPA) mode.

When the light source system 10 includes a plasma-based light source, the light source system 10 may further include a collecting mirror, such as an elliptical mirror or a spherical mirror, to increase energy density of extreme ultraviolet light incident to the illumination optical system 20.

The illumination optical system 20 may include a plurality of illumination mirrors. In the semiconductor process apparatus 1 according to one or more embodiments, the illumination optical system 20 may include two or more illumination mirrors. The illumination optical system 20 may transmit extreme ultraviolet light emitted by the light source system 10 to the mask stage 40. The extreme ultraviolet light emitted by the light source system 10 may be reflected by the illumination mirrors included in the illumination optical system 20 and may be incident to the mask M seated on the mask stage 40.

In one or more embodiments, the mask M may be configured as a reflective mask including a non-reflective region and/or an intermediate reflective region together with a reflective region. The mask M may include a reflective multilayer film formed on a wafer formed of a relatively low thermal expansion coefficient material (LTEM) such as quartz to reflect extreme ultraviolet light, and an absorption layer pattern formed on the reflective multilayer film. The reflective multilayer film may have a structure in which layers formed of different materials are stacked. The absorption layer may be formed of tantalum nitride (TaN), tantalum nitrogen oxide (TaNO), tantalum boron oxide (TaBO), nickel (Ni), gold (Au), silver (Ag), carbon (C), tellurium (Te), platinum (Pt), palladium (Pd), chromium (Cr), or the like. However, the material of the absorption layer is not limited to the materials mentioned above, and the absorption layer portion may correspond to the non-reflective region and/or the intermediate reflective region described above.

The mask M may reflect extreme ultraviolet light incident to the illumination optical system 20 and may enable extreme ultraviolet light to be incident to the projection optical system 30. The projection optical system 30 may include a plurality of projection mirrors. Each of the plurality of projection mirrors included in the projection optical system 30 may include a mirror body and a reflective layer attached to a surface of the mirror body. The projection optical system 30 may be an imaging optical system disposed between the mask stage 40 and the wafer stage 50. For example, the extreme ultraviolet light passing through the illumination optical system 20 may be structured according to a pattern shape including a reflective multilayer film and an absorption layer on a wafer in the mask M and may be incident to the projection optical system 30.

The extreme ultraviolet light may be structured to include at least second-order diffraction light based on the pattern on the mask M. The structured extreme ultraviolet light may be incident to the projection optical system 30 while having information on the shape of the pattern included in the mask M, and may be irradiated (emitted) to the wafer W seated on the wafer stage 50 through the projection optical system 30 so as to form an image corresponding to the shape of the pattern included in the mask M, which may correspond to the exposure process during the photolithography process. According to one or more embodiments, the structured extreme ultraviolet light passing through the projection optical system 30 may be incident to a process target other than the wafer W.

The extreme ultraviolet light reflected from the mask M and passing through the projection optical system 30 may be incident to an upper surface of the wafer W while forming a predetermined slope. For example, the projection optical system 30 may adjust a traveling path of the extreme ultraviolet light such that the extreme ultraviolet light may be incident while forming an incident angle of about 6 degrees with the upper surface of the wafer W.

The mask M may be seated on the mask stage 40, and the wafer W may be seated on the wafer stage 50. For example, the mask stage 40 and the wafer stage 50 may be controlled by the controller 60. In the initial state in which the mask M and the wafer W are seated on the mask stage 40 and the wafer stage 50, respectively, when the upper surfaces of the mask M and the wafer W are defined as the X-Y plane, the mask stage 40 and the wafer stage 50 may move by the controller 60.

In one or more embodiments, the controller 60 may rotate each of the mask stage 40 and the wafer stage 50 on the X-Y plane with the Z-axis as a reference, or on the y-z plane or the x-z plane with one axis on the X-Y plane as a reference. By the movement of the mask stage 40 and/or the wafer stage 50 as described above, the mask M and/or the wafer W may move or rotate along the X-axis, the Y-axis, and the Z-axis in three-dimensional space.

The measurement unit 70 may measure overlays of a plurality of patterns formed on the wafer W, a position of the alignment mark, or the like. For example, the measurement unit 70 may include an electron microscope or an optical microscope, such as a scanning electron microscope (SEM) or a transmission electron microscope (TEM). Also, the measurement unit 70 may measure the position of the overlay or the alignment mark using image ellipsometry, spectroscopic image ellipsometry, or the like. According to one or more embodiments, the measurement unit 70 may be provided as a device separate from the semiconductor process apparatus 1.

As a semiconductor process such as the example described above is performed, a plurality of layers including different patterns may be generated on the wafer W. To ensure proper operation of the semiconductor device manufactured from the wafer W, a plurality of layers may need to be properly aligned and stacked.

The plurality of layers may be aligned using the position of the alignment mark. The position of the alignment mark of the lower layer may be measured before performing an exposure process for the upper layer. The position of the pattern formed on the lower layer may be determined using the position of the alignment mark.

The controller 60 may determine and align the positions of the wafer W and the mask M using the position of the alignment mark of the lower layer. For example, the controller 60 may move the positions of the wafer W and/or the mask M. After the wafer W and mask M are properly aligned, a photoresist layer applied on the lower layer may be exposed, thereby forming a predetermined pattern on the upper layer. After performing a subsequent semiconductor process, the measurement unit 70 may measure an overlay, which is an alignment error of the upper layer and the lower layer.

The measurement unit 70 may obtain measurement data by measuring the position of the alignment mark based on the multiwavelength light. The multiwavelength light may include a plurality of beams of light having different wavelengths. For example, the multiwavelength light may include red, green, near infrared (NIR), and far infrared (FIR). However, the plurality of beams of light included in the multiwavelength light may not be limited thereto. The measurement data may include the position of the alignment mark for each wavelength, and the position of the alignment mark may be represented as coordinates with respect to the X-axis and the Y-axis.

After the alignment mark is formed, the alignment mark may be deformed as subsequent semiconductor processes are performed. For example, the alignment mark may be deformed by semiconductor processes such as etching, chemical mechanical polishing (CMP), or baking of the wafer W. When the alignment mark is deformed, the positions of the alignment mark measured by each wavelength may be different.

In one or more embodiments, the measurement unit 70 may derive a final position of the alignment mark by applying a weight to the measurement data. The weight may include a plurality of weight components assigned to a plurality of beams of light included in the multiwavelength light, respectively. The weight may be determined by the controller 60. For example, the weight may be determined using overlay data measured in a prior semiconductor process.

In one or more embodiments, overlay data and/or measurement data measured in the plurality of semiconductor process apparatus, and different types of indices derived from the pieces of data may be reflected in the weight. For example, the indices may be values representing dispersion of the overlay data or values representing accuracy of the position of the alignment mark. For example, the weight may be determined by comprehensively evaluating the position of the alignment mark of the plurality of semiconductor process apparatuses and different types of dispersion of overlays. Accordingly, the error of the actual position of the final position of the alignment mark may be reduced, such that the overlay may be addressed and the yield of the semiconductor process may improve.

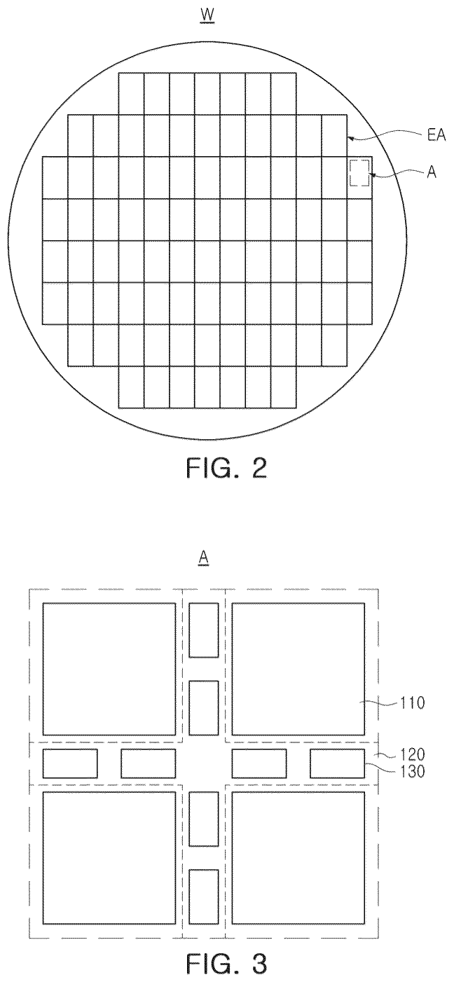

FIG. 2 is a diagram illustrating a wafer according to one or more embodiments. FIG. 3 is an enlarged diagram illustrating region “A” illustrated in FIG. 2.

Referring to FIG. 2, a wafer W according to one or more embodiments may include a plurality of exposure regions EA. The exposure region EA may be a unit region exposed by a single exposure process. For example, the exposure region EA may be a unit region in which a pattern is transferred to a photoresist layer by extreme ultraviolet light. For example, when the wafer W includes 100 exposure regions EA, the exposure process may be performed on the wafer W 100 times.

Referring to FIG. 3, the wafer W according to one or more embodiments may include a plurality of die regions 110 including a plurality of chips, and a scribe line region 120 defined between the plurality of die regions 110. The plurality of die regions 110 may be isolated from each other by the scribe line region 120. The scribe line region 120 may include a cutting region cut by a sawing machine or a dicing machine.

A plurality of elements, such as a transistor, a capacitor, and a resistor, included in an integrated circuit may be formed in each of the plurality of die regions 110. A plurality of alignment mark regions 130 may be disposed in the scribe line region 120. As one or more embodiments illustrated in FIG. 3, the plurality of alignment mark regions 130 may be spaced apart from each other within the scribe line region 120 by a predetermined spacing. However, one or more embodiments thereof is not limited thereto.

At least one alignment mark may be disposed in the alignment mark region 130. The alignment mark may have various shapes, such as, for example, a circular shape, a quadrangular shape, and/or a cross shape, and may have a combined shape of the above-mentioned shapes. The alignment mark may be a reference for aligning the exposure region of the wafer W with the mask before an exposure process is performed in the exposure region EA, as in the example described with reference to FIG. 1 above.

Multiwavelength light and weight may be used to derive the position of the alignment mark. The weight may reflect measurement data obtained by measuring overlay data and/or alignment mark positions in a preceding semiconductor process.

The general weight may be determined by considering overlay data measured in a single semiconductor process apparatus and a single type of dispersion of overlay derived from the overlay data. When the general weight is applied to a different semiconductor process apparatus, the dispersion of overlay may be deteriorated. Also, when a different type of dispersion of overlay is derived from the overlay data, the different type of dispersion of overlay may be relatively deteriorated. For example, the general weight may not be optimal for a different semiconductor process apparatus and/or a different dispersion of overlay.

However, embodiments are not limited thereto. For example, the weight in one or more embodiments may be determined by considering overlay data measured in the plurality of semiconductor process apparatuses and different types of dispersion of overlays derived from the overlay data. Also, the weight may also be determined by considering accuracy of the alignment mark positions. Accordingly, even when different types of dispersion of overlays are derived by applying the weight in one or more embodiments to the plurality of semiconductor process apparatuses to derive, the derivation may be determined to be optimal.

A plurality of dispersion of overlays derived from the overlay measured in a plurality of semiconductor process apparatuses and/or accuracy of the position of the alignment mark measured in the plurality of semiconductor process apparatus may be reflected in the weight in one or more embodiments. For example, a weight which may improve accuracy of the final position of the alignment mark may be determined by comprehensively considering the plurality of semiconductor process apparatuses and the plurality of dispersion of overlays. As another example, the weight may be determined by also considering accuracy of the position of the alignment mark. As the error between the final position and the actual position of the alignment mark is reduced, the overlay may be addressed and the yield of the semiconductor process may be improved.

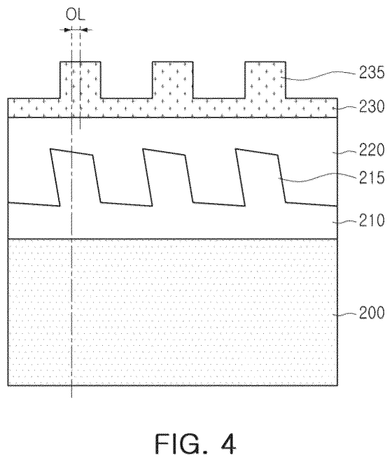

FIG. 4 is a diagram illustrating overlay caused by deformation of a shape of first structures according to one or more embodiments.

Alignment marks disposed in an alignment mark region 130 will be described with reference to FIGS. 1 to 3 together. Referring to FIG. 4, a first layer 210, a second layer 220, and a third layer 230 may be stacked and formed in that order on a wafer 200. First structures 215 may be formed on the first layer 210, and second structures 235 may be formed on the third layer 230. The first structures 215 and the second structures 235 may correspond to alignment marks.

A semiconductor process apparatus may form a first layer 210 on a wafer 200, and a photoresist layer on the first layer 210. The semiconductor process apparatus may perform an exposure process, and extreme ultraviolet light reflected from a mask may be irradiated (emitted) on the photoresist layer, thereby forming a pattern. By performing an etching process on the first layer 210 and removing the photoresist layer, first structures 215 may be formed on the first layer 210. Thereafter, the semiconductor process apparatus may form the second layer 220 and the third layer 230. In this case, the shape of the first structures 215 may be deformed.

The semiconductor processes performed on the first layer 210 may also be performed on the third layer 230. Before the exposure process is performed on the photoresist layer formed on the third layer 230, the semiconductor process apparatus may measure the position of the first structures 215 using multiwavelength light. Also, the semiconductor process apparatus may derive the final position of the alignment mark by applying a weight to the measured measurement data.

Due to the deformed shape of the first structures 215, the final position of the alignment mark may have an error with the actual position, and the semiconductor process apparatus may align the wafer and the mask using the final position of the alignment mark including the error. Accordingly, as in one or more embodiments illustrated in FIG. 4, an overlay OL may occur between the first structures 215 and the second structure 235.

As one or more embodiments, the weight may be determined by comprehensively considering the plurality of semiconductor process apparatuses and the plurality of dispersion of overlays. As another example, the weight may be determined by considering accuracy of the final position of the first structures 215. Accordingly, in the plurality of semiconductor process apparatuses, the error between the final position of the alignment mark and the actual position may be reduced.

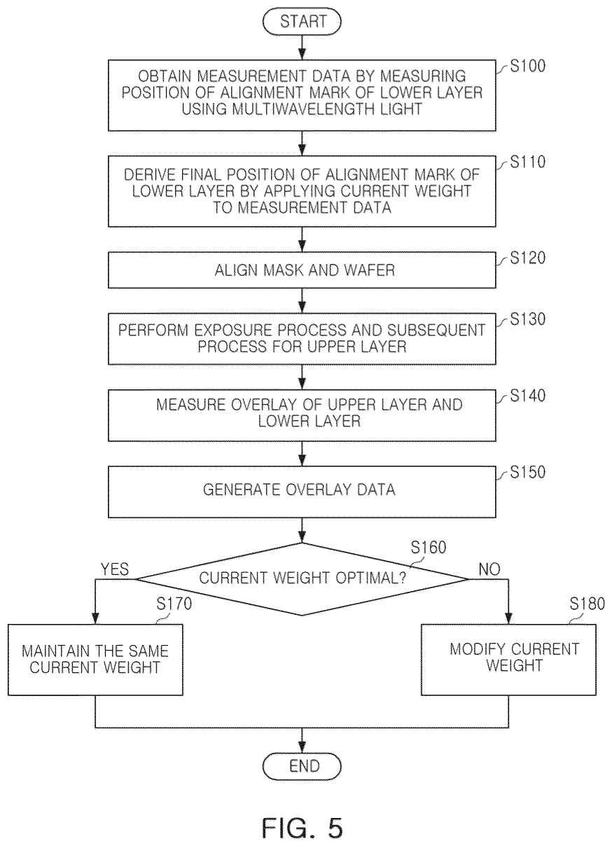

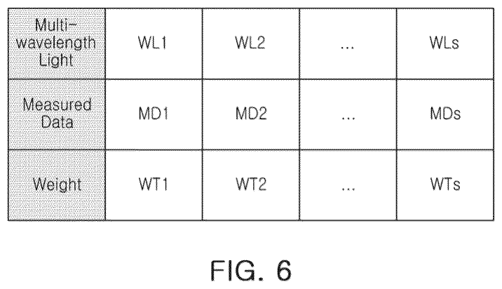

FIG. 5 is a flowchart illustrating a process of performing a semiconductor process apparatus according to one or more embodiments. FIG. 6 is a diagram illustrating multiwavelength light according to one or more embodiments.

A semiconductor process apparatus may be configured to perform a photolithography process, and may include a light source system, an illumination optical system, a projection optical system, a mask stage, a wafer stage, a controller, and a measurement unit. The semiconductor process apparatus may generate a plurality of layers including different patterns on a wafer, and the plurality of layers may need to be properly aligned and stacked. The alignment of the plurality of layers may be controlled using alignment marks. One or more embodiments of the semiconductor process apparatus may be similar to the examples described with reference to FIGS. 1 to 4 above.

Referring to FIGS. 5 and 6 together, the measurement unit may obtain measurement data by measuring the position of the alignment mark of the lower layer using multiwavelength light (S100). The multiwavelength light may include a plurality of beams of light WL1-WLs having different wavelengths, where s is a natural number. The measurement data may include position MD1-MDs of the alignment mark for each wavelength, and the position MD1-MDs of the alignment mark may be represented as coordinates with respect to the X-axis and the Y-axis.

In one or more embodiments, each of the plurality of beams of light WL1-WLs may have different sensitivities to deformation of the alignment mark. The plurality of beams of light WL1-WLs may measure the position of the alignment mark differently. For example, when the alignment mark is not deformed, the positions MID1-MDs of the alignment mark may be the same. In another example, when the alignment mark is deformed, at least one of the positions MD1-MDs of the alignment mark may be different.

The measurement unit may derive the final position of the alignment mark of the lower layer by applying the current weight to the measurement data (S110). A plurality of weights may be applied to the multiwavelength light, and the current weight may correspond to a weight applied to the multiwavelength light among the plurality of weights.

The weight may include a plurality of weight components WT1-WTs assigned to the plurality of beams of light included in the multiwavelength light, respectively. At least one of the plurality of weight components WT1-WTs may be different. Each of the plurality of weight components WT1-WTs may be positive, negative, or 0. The sum of the plurality of weight components WT1-WTs may be 1.

As an example, the measurement unit may derive the final position of the alignment mark by multiplying the weight component WT corresponding to each of the measurement data MD1-MDs and summing the resulting values. In this case, the final X-axis position and the final Y-axis position of the alignment mark may be derived by multiplying the weight component WT corresponding to each of the X-axis value and Y-axis value of the measurement data MD1-MDs and summing the resulting values. However, the method of deriving the final position of the alignment mark may not be limited thereto.

The controller may move the mask stage and the wafer stage using the final position of the alignment mark of the lower layer as a reference. For example, the controller may align the mask and the wafer such that the pattern may be exposed to a predetermined region of the wafer (S120). For example, the controller may align the mask and the wafer by adjusting the positions of the mask stage and the wafer stage. The semiconductor process apparatus may perform an exposure process and a subsequent process for the upper layer (S130). In this case, an alignment mark may be formed on the upper layer.

The measurement unit may measure overlay, which is an alignment error of the upper layer and the lower layer (S140). The measurement unit may transmit the measured overlay to the controller. The controller may store the overlay received from the measurement unit. The operations S100 to S140 may be repeatedly performed for a predetermined period of time and the overlay may be accumulated, thereby generating overlay data (S150). The predetermined period of time may correspond to several hours, several days, or a period of time during which the process is performed on a predetermined number of wafers, but one or more embodiments thereof is not limited thereto.

It may be determined whether the current weight is optimal based on the measurement data and/or overlay data (S160). When the current weight is determined to be optimal based on the measurement data and/or overlay data corresponding to a predetermined value, (YES of S160), the controller may maintain the same current weight (S170). When the current weight is determined not to be optimal based on the measurement data and/or overlay data not corresponding to the predetermined value (NO of S160), the controller may modify the current weight (S180). The controller may transmit the modified weight to the measurement unit, and the measurement unit may derive the final position of the alignment mark by applying the modified weight.

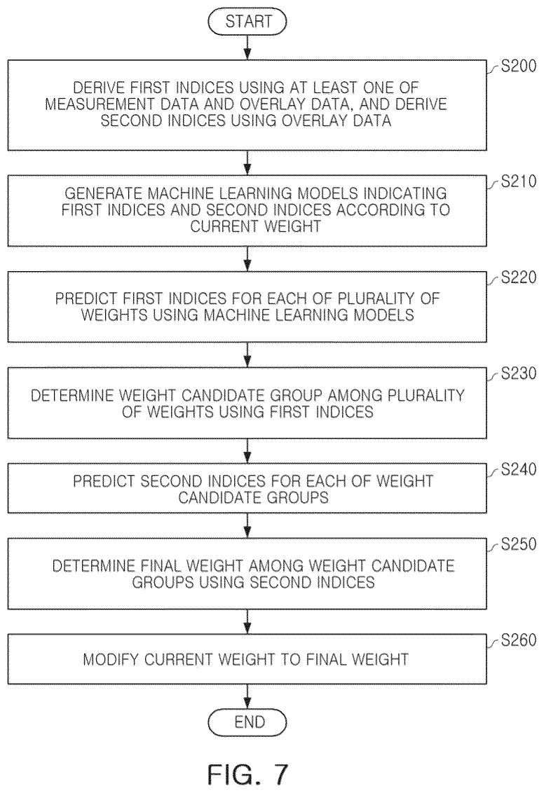

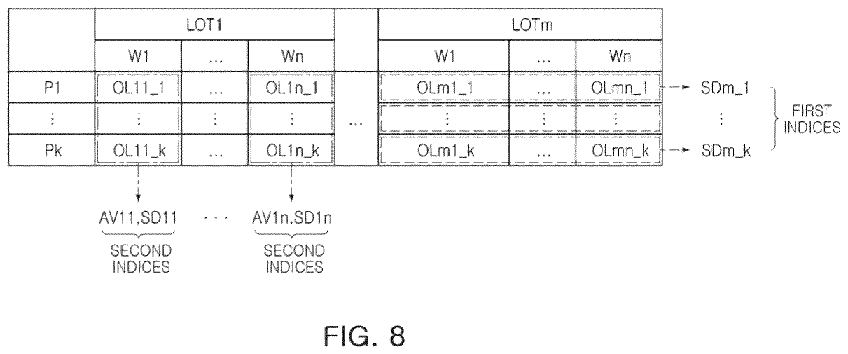

As one or more embodiments, the reference for determining whether the current weight is optimal may be overlay data. For example, a plurality of dispersion of overlays may be derived using overlay data for the plurality of semiconductor process devices as a reference, and the plurality of dispersion of overlays may be used to determine whether the current weight is optimal. Hereinafter, the process of modifying the current weight will be described in greater detail with reference to FIGS. 7 to 8.

FIG. 7 is a flowchart illustrating a process of controlling a current weight according to one or more embodiments. FIG. 8 is a diagram illustrating overlay data and indices in one or more embodiments.

The semiconductor process apparatus may be configured to perform a photolithography process, and may include a light source system, an illumination optical system, a projection optical system, a mask stage, a wafer stage, a controller, and a measurement unit. The measurement unit may measure an overlay by applying a current weight to a multiwavelength light and may transmit the overlay to the controller. The controller may generate overlay data by accumulating the overlay received from the measurement unit.

The controller may determine whether the weight is optimal using the overlay data, and may maintain or modify the current weight. One or more embodiments of the semiconductor process apparatus may be similar to the examples described with reference to FIGS. 1 to 6 above. Hereinafter, the process of determining whether the current weight is optimal (S160 in FIG. 5) and the process of modifying the current weight (S180 in FIG. 5) will be described in greater detail.

Referring to FIG. 7, the controller may derive first indices using at least one of measurement data and overlay data, and may derive second indices using the overlay data (S200). In this case, the first indices and the second indices derived using the overlay data may represent distribution of overlay for a plurality of measurement positions of the wafer, and the first indices may be different types of indices from the second indices. The first indices derived using measurement data may represent accuracy of the final position of the alignment mark for the plurality of measurement positions of the wafer.

The controller may generate machine learning models indicating the first indices and the second indices according to the current weight (S210). The machine learning models may analyze the first indices and the second indices according to the current weight and may learn patterns. Accordingly, the machine learning models may be used to predict the overlay, the first indices, and/or the second indices. For example, referring to FIG. 8, the first index and the second index in one or more embodiments will be described.

Referring to FIG. 8, the semiconductor process may be performed by lot units, and the semiconductor process may be performed on a plurality of lots LOT1-LOTm, where m is a natural number. The semiconductor process may be performed in order from the first lot LOT1 to the mth lot LOTm, or may be performed in an arbitrary order. Each of the plurality of lots LOT1-LOTm may include a plurality of wafers W1-Wn, where n is a natural number. A plurality of wafers W1-Wn included in the same lot may be input into the same semiconductor process apparatus and the semiconductor process may be performed, or at least one wafer W may be input into a different semiconductor process apparatus and the semiconductor process may be performed.

The measurement unit may measure the overlay at a plurality of measurement positions P1-Pk of the wafer W, where k is a natural number. In this case, the overlay may be measured from a multiwavelength light to which current weights are applied. The controller may predict the overlay for each of the plurality of weights using machine learning models. However, the controller may not be limited to machine learning models, and the controller may predict an overlay for each plurality of weights using full research or gradient descent, or the like.

A plurality of measurement positions P1-Pk may be different positions of the wafer W. For each of the plurality of wafers W1-Wn included in the plurality of lots LOT1-LOTm, overlays OL11_1-OLmn_k of the plurality of measurement positions P1-Pk may be measured or predicted. Each of the overlays OL11_1-OLmn_k may include an X-axis value and a Y-axis value.

For example, the overlays OL11_1-OLmn_k in one or more embodiments illustrated in FIG. 8 may be overlay data in which the current weight is measured from a multiwavelength light. As another example, the overlays OL11_1-OLmn_k in one or more embodiments illustrated in FIG. 8 may be overlay data predicted by machine learning models by applying one of a plurality of weights to the multiwavelength light.

As one or more embodiments illustrated in FIG. 8, the first index and the second index may be derived from the overlay data. In this case, the first index may represent the dispersion of overlay of wafers included in a single lot, and the second index may represent the dispersion of overlay for a single wafer.

As another example embodiment not illustrated in FIG. 8, the first index may represent the dispersion of overlay for a single wafer, and the second index may represent the dispersion of overlay for wafers included in a single lot. Hereinafter, the first index and the second index in one or more embodiments illustrated in FIG. 8 will be described.

The first index in one or more embodiments illustrated in FIG. 8 may be derived from the overlay data among the measurement data and the overlay data. In one or more embodiments, the first index may represent the dispersion of overlay of wafers included in a single lot. For example, the first index may be a value for the overlay standard deviation for each of the plurality of measurement positions P1-Pk of wafers included in a single lot. The first index may include the standard deviation for the X-axis value of the overlays OL11_1-OLmn_k and/or the standard deviation for the Y-axis value of the overlays OL11_1-OLmn_k.

In the mth lot LOTm, the standard deviations SDm1-SDmk of the overlays OLm1_1-OLmn_k of the first to nth wafers W1-Wn may be derived for the plurality of measurement positions P1-Pk, respectively. At the first measurement position P1, the standard deviation SDm1 of the overlays OLm1_1-OLmn_1 may be derived, and at the kth measurement position Pk, the standard deviation SDmk of the overlays OLm1_k-OLmn_k may be derived. As one or more embodiments, the first index may be an average of three times the value of the standard deviations SDm1-SDmk. However, one or more embodiments thereof is not limited thereto.

The second index may be derived from the overlay data. In one or more embodiments, the second index may represent the dispersion of overlay for a single wafer. For example, the second index may be a value for an overlay and a standard deviation of overlays of the plurality of measurement positions P1-Pk for a single wafer.

In one or more embodiments, the second index may be a sum of the absolute value of the average of the overlays and a value three times the standard deviation of the overlay. The second index may be a sum of the absolute value of the average for the X-axis value of the overlays OL11_1-OLmn_k and a value three times the standard deviation of the X-axis value of overlays OL11_1-OLmn_k. As another example, the second index may be a sum of the absolute value of the average for the Y-axis value of the overlays OL11_1-OLmn_k and a value three times the standard deviation of the Y-axis value of the overlays OL11_1-OLmn_k.

For the first wafer W1 of the first lot LOT1, the average AV11 and the standard deviation SD11 of the overlays OL11_1-OL11_k for each of the plurality of measurement positions P1-Pk may be derived. For the first wafer W1 of the first lot LOT1, the first index may be the sum of the absolute value of the average AV11 of the overlays OL11_1-OL11_k and a value three times the standard deviation SD11 of the overlays OL11_1-OL11_k.

For the nth wafer Wn of the first lot LOT1, the average AV1n and the standard deviation SD1n of the overlays OL1n_1-OL1n_k for each of the plurality of measurement positions P1-Pk may be derived. For the nth wafer Wn of the first lot LOT1, the first index may be the sum of the absolute value of the average AV1n of the overlays OL1n_1-OL1n_k and a value three times the standard deviation SD1n of the overlays OL1n_1-OL1n_k.

However, embodiments are not limited thereto. For example, the first index may be derived from the measurement data. The first indices derived using the measurement data may represent accuracy of the final position of each alignment mark for each of the plurality of beams of light for each of the plurality of measurement positions of the wafer.

FIG. 6 may represent the measurement data for a single measurement position. For example, the measurement data for the single measurement position may include the positions MD1-MDs of the alignment marks for each of the plurality of beams of light WL1-WLs. The first index may be derived using the positions MD1-MDs of the alignment marks.

For example, the first index derived using the measurement data may include wafer quality (WQ), multiple correlation coefficient (MCC), residual overlay performance indicator (ROPI), and/or random process noise (RPN). However, the type and/or number of the first index may not be limited thereto. The first index derived using the measurement data may also be included in the S200 and S210 processes in FIG. 7 described above. WQ may be an index indicating whether the position of the alignment mark is measured repeatedly in the same alignment mark. MCC may be an index indicating the degree to which the position of the alignment mark matches the reference position.

ROPI may be an index for the residual between the measurement data of the single wafer and the modeling function by deriving the modeling function by modeling the measurement data of the single wafer. RPN may be an index of a difference between the average of the ROPI and the measurement data for each of the plurality of measurement positions of the wafer by deriving the average of ROPI for each of the plurality of measurement positions of wafers included in a single lot.

The controller may predict first indices for each of the plurality of weights using machine learning models (S220). The controller may determine a weight candidate group among the plurality of weights using the first indices (S230). The weight candidate group may include at least one of the weights included in the plurality of weights.

The controller may predict second indices for each of the weight candidate groups using machine learning models (S230). The controller may determine a final weight among the weight candidate groups using the second indices (S250). The final weight may correspond to one of the weight candidate groups.

The controller may modify the current weight to the final weight (S260). Thereafter, the final position of the alignment mark may be derived by reflecting the final weight on the measurement data, and the error between the final position of the alignment mark and the actual position may be reduced.

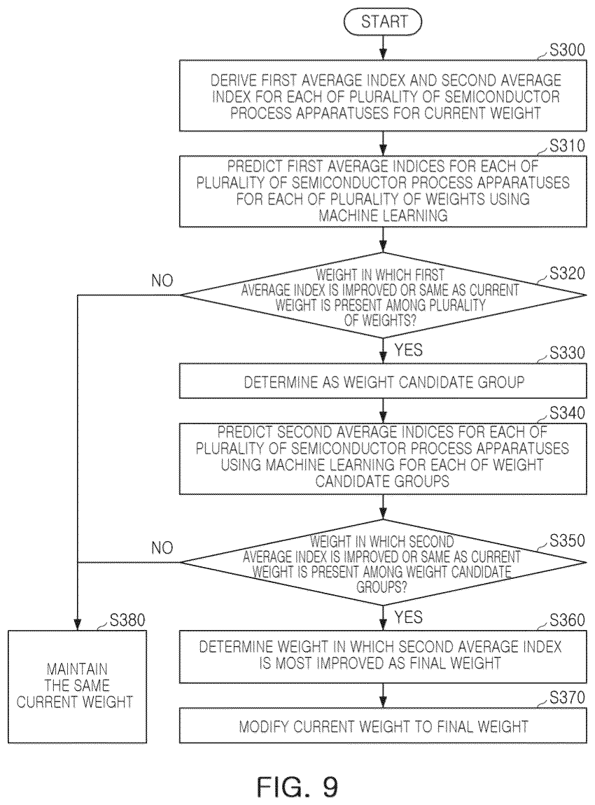

Hereinafter, the process of controlling a weight will be described in greater detail with reference to FIGS. 9 to 13.

FIGS. 9 to 13 are diagrams illustrating a process of controlling a weight according to one or more embodiments.

The same semiconductor process may be performed in a plurality of semiconductor process apparatuses. In this case, the semiconductor process may be a photolithography process, and the semiconductor process apparatus may be an apparatus for performing the photolithography process. One or more embodiments of the semiconductor process apparatus may be similar to the examples described with reference to FIGS. 1 to 8 above.

The current weight in one or more embodiments may be applied equally to the plurality of semiconductor process apparatuses. The current weight may be modified by referring to measurement data and/or overlay data measured in the plurality of semiconductor process apparatuses. The controller may determine whether to modify the current weight by deriving and predicting first indices and second indices and comparing the indices with each other.

Referring to FIG. 9, the controller may derive a first average index and a second average index for each of the plurality of semiconductor process apparatuses for the current weight (S300). The first indices and the second indices for each of the plurality of semiconductor process apparatuses may be derived from at least one wafer on which the semiconductor process is performed in the same apparatus among the plurality of semiconductor process apparatuses. The first average index may be an average of the first indices, and the second average index may be an average of the second indices.

The controller may predict the first average indices for each of the plurality of semiconductor process apparatuses for each of the plurality of weights using machine learning (S310). The controller may determine whether a weight in which the first average index is improved or the same as the current weight is present among the plurality of weights (S320).

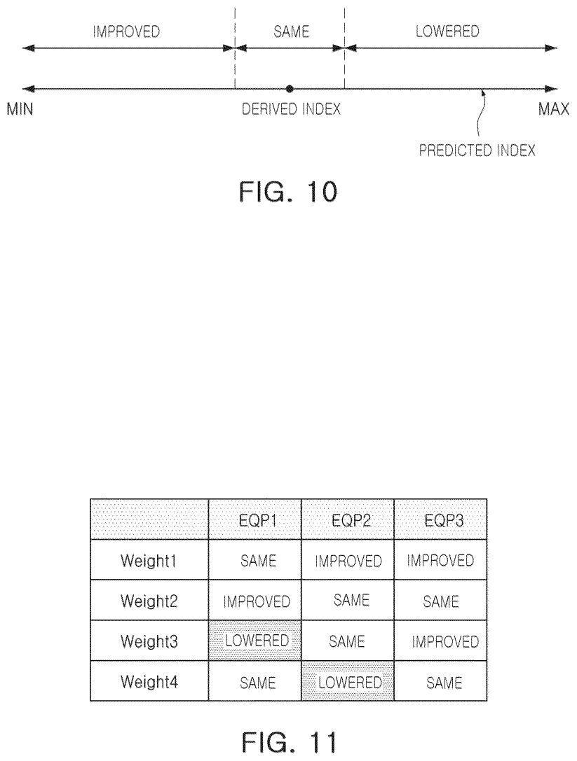

Referring to FIG. 10 together, FIG. 10 may be a diagram illustrating determination of comparison between a predicted index and a derived index in one or more embodiments. In this case, the derived index may be an index derived from measured overlay data, and the predicted index may be an index predicted using machine learning models. The index may include a first index, a first average index, a second index, and a second average index.

When the predicted index is within a predetermined range of the derived index, the predicted index may be determined to be the same as the derived index. For example, when the predicted index and the derived index are derived from overlay data, and the predicted index is different from the derived index by less than 1 Å (Angstrom, 0.1 nm), the predicted index and the derived index may be determined to be the same. However, the predetermined range may not be limited thereto.

When the predicted index is beyond the predetermined range and is greater than the derived index, the predicted index may be determined to be degraded as compared to the derived index. When the predicted index is beyond the predetermined range and is smaller than the derived index, the predicted index may be determined to be improved as compared to the derived index.

Referring to FIG. 11, FIG. 11 may be a diagram illustrating determining a weight candidate group among a plurality of weights in one or more embodiments. The comparison of the first average index may be performed for each semiconductor process apparatus for each of the plurality of weights. The result of the comparison of the first average index may correspond to one of being the same, improved, and deteriorated.

As one or more embodiments illustrated in FIG. 11, the semiconductor process may be performed in the first to third semiconductor process apparatus, and the plurality of weights may include the first to fourth weights. FIG. 11 may illustrate the result of comparing the first average index for each of the first to third semiconductor process apparatus for each of the first to fourth weights.

The first index may be derived from overlay data. For example, the first index may be an average of three times the value of each overlay standard deviation of a plurality of measurement positions of wafers included in a single lot. As another example, the first index may be a sum of the average of overlays of the plurality of measurement positions included in a single wafer and a value three times the overlay standard deviation. However, the type of the first index is not limited thereto, and the first index may further include indices derived from measurement data such as WQ, MCC, ROPI, and/or RPN.

Referring to FIG. 9, when a weight in which the first average index is improved or the same as the current weight is present among the plurality of weights (YES in S320), the controller may determine the weight as a weight candidate group (S330).

Referring to FIG. 11 together, in the first and second weights, the first to third semiconductor process apparatus may include a first average index which may be improved or the same as the current weight. For example, in the first and second weights, the first average index, which is lowered as compared to the current weight, may not be included in the first to third semiconductor process apparatus. Accordingly, the first and second weights may be determined as weight candidate groups.

In the third weight, the first average index, which is lowered as compared to the current weight, may be included in the first semiconductor process apparatus. In the fourth weight, the first average index, which is lowered as compared to the current weight, may be included in the second semiconductor process apparatus. For example, the third and fourth weights may not be determined as weight candidates.

Referring to FIG. 9, when no weight in which the first average index is improved or the same as the current weight is present among the plurality of weights (NO of S320), the controller may maintain the current weight the same (S380). For example, the current weight may not be modified. As another example, in the first and second weights, when at least one of the first to third semiconductor process apparatuses includes the first average index, which is lowered as compared to the current weight, the current weight may be maintained the same.

As another example, the S320 process may be performed for a plurality of first indices. For example, when the first index further includes indices for WQ, MCC, ROPI, and/or RPN, the S320 process may also be performed for the further included first indices. In this case, the weight candidate may include a first average index, which is improved or the same as the current weight, in the first to third semiconductor process apparatuses for all types of first indices.

The controller may predict second average indices for each of the plurality of semiconductor process apparatuses using machine learning for each of the weight candidate groups (S340). The controller may determine whether a weight in which the second average index is improved or the same as the current weight is present among the weight candidate groups (S350).

In this case, the second index may be a different type of index from the first index. For example, the second index may be the sum of the average of overlays of a plurality of measurement positions included in a single wafer and a values three times the overlay standard deviation. As another example, the second index may be the average of the values three times the overlay standard deviation of each of the plurality of measurement positions of wafers included in a single lot. However, the type of the second index may not be limited thereto.

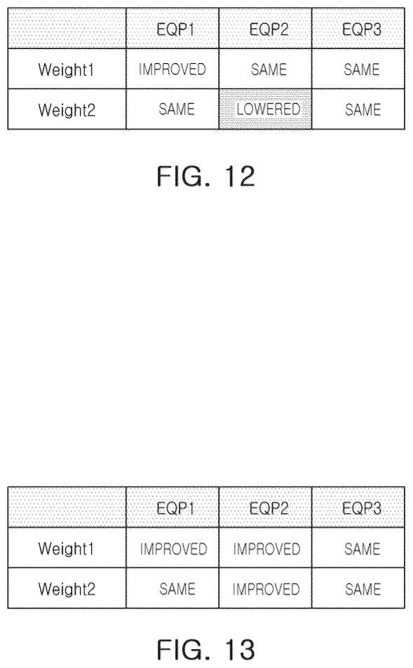

Referring to FIGS. 12 and 13 together, FIGS. 12 and 13 may be diagrams illustrating determining a final weight among weight candidate groups in example embodiments. The weight candidate groups in FIGS. 12 and 13 may include first and second weights, and may be weight candidate groups determined in FIG. 11. The semiconductor process may be performed in a first to third semiconductor process apparatus, which may be similar to FIG. 11.

Referring to FIG. 9, when a weight in which the second average index is improved or the same as the current weight is present among the weight candidate groups (YES of S350), the controller may determine a weight in which the second average index is the most improved, the predicted index being beyond the predetermined range and having a smallest value compared to the derived index, as a final weight (S360). The controller may modify the current weight to the final weight (S370).

In one or more embodiments illustrated in FIG. 12, in the first weight, the second average index, which is improved or the same as the current weight, may be included in the first to third semiconductor process apparatus. In the second weight, the second average index, which is lowered as compared to the current weight, may be included in the second semiconductor process apparatus. For example, in the first to third semiconductor process apparatus, the weight in which the second average index is the most improved may be the first weight, such that the first weight may be determined as the final weight. The current weight may be modified to the first weight.

In one or more embodiments illustrated in FIG. 13, in the first and second weights, the first to third semiconductor process apparatus may include a second average index, which is improved or the same as the current weight. In the first weight, the first and second semiconductor process apparatus may include a second average index, which is improved as compared to the current weight. In the second weight, only the second semiconductor process apparatus may include the second average index, which is improved as compared to the current weight. For example, in the first to third semiconductor process apparatus, since the weight having the most improved second average index is the first weight, the first weight may be determined as the final weight. The current weight may be modified to the first weight.

Referring to FIG. 9, when no weight in which the second average index is improved or the same as the current weight is present among the weight candidate groups (NO of S320), the controller may maintain the current weight to be the same (S380). For example, the current weight may not be modified and maintained. As another example, in the first and second weights, when at least one of the first to third semiconductor process apparatuses includes a second average index, which is lowered as compared to the current weight, the current weight may be maintained to be the same.

The weight in the example embodiment described with reference to FIGS. 9 to 13 may be applied equally to a plurality of semiconductor process apparatuses. For example, the weight may be applied equally to the entire region of the wafer.

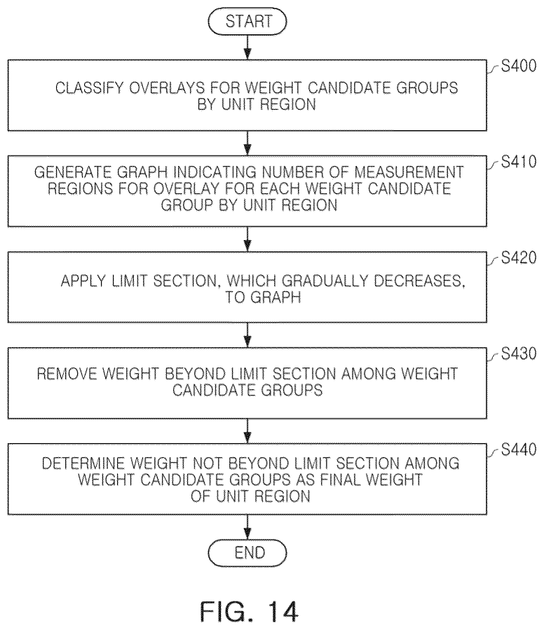

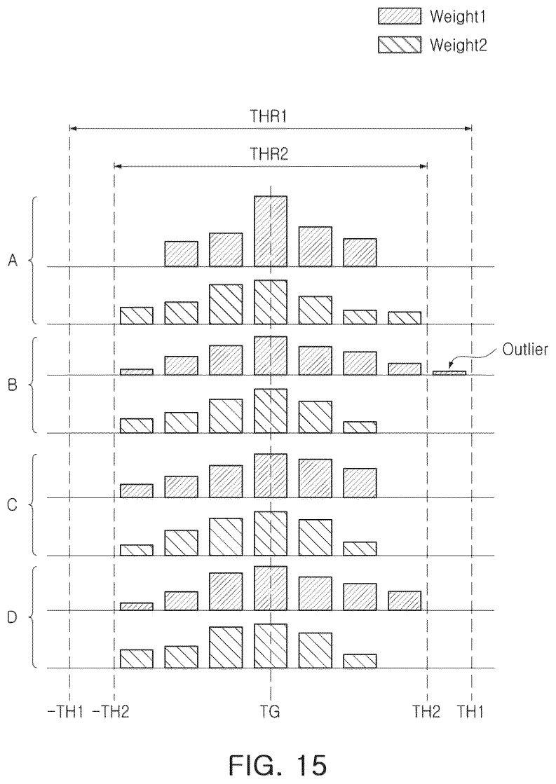

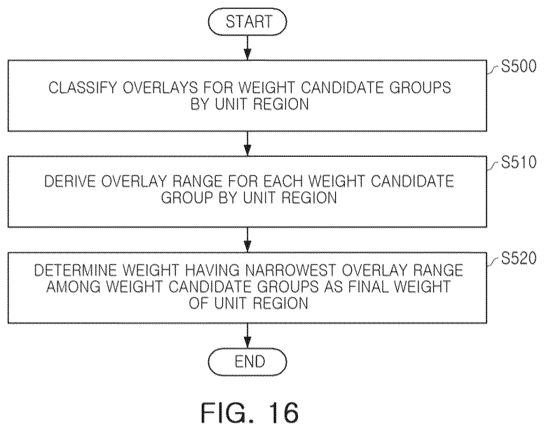

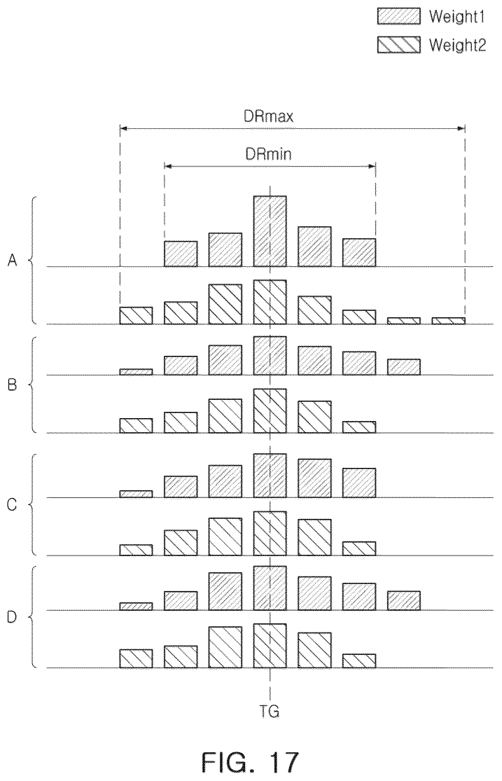

FIGS. 14 and 15 are diagrams illustrating a process of determining a final weight of a unit region using a limit section according to one or more embodiments. FIGS. 16 and 17 are diagrams illustrating a process of determining a final weight of a unit region using an overlay range according to one or more embodiments.

The same semiconductor process may be performed in a plurality of semiconductor process apparatuses. One or more embodiments of the semiconductor process apparatus may be similar to the examples described with reference to FIGS. 1 to 8 above.

The controller may derive first indices for the current weights using the measurement data and/or overlay data, and may derive second indices using the overlay data. The controller may predict the first indices for each of the plurality of weights by generating machine learning models. The controller may determine a weight candidate group among the plurality of weights using the first indices for each of the plurality of semiconductor process apparatuses. The controller may predict the second indices for each of the plurality of candidate groups. The processes may be similar to the examples described with reference to FIGS. 9 to 11 above.

Comparing FIGS. 14 to 17 with FIGS. 9 to 13, the final weight determined in FIGS. 9 to 13 may be applied to the entire region of the wafer. Referring to FIG. 2 together, the final weight determined in FIGS. 12 and 13 may be applied equally to a plurality of exposure regions EA.

The final weight determined in FIGS. 14 to 17 may be applied to the unit region. The controller in the one or more embodiment may determine the final weight among the weight candidate group for each unit region using the second indices distinguished for each unit region. For example, a different the final weight may be applied for each unit region.

Referring to FIG. 2 together, the unit region may correspond to a single exposure region EA or a plurality of exposure regions EA. In this case, the plurality of exposure regions EA may be adjacent exposure regions EA, or at least one exposure region EA may not be adjacent to the other of the plurality of exposure regions EA. However, the definition of the unit region may not be limited thereto.

A method of determining the final weight of the unit region using the limit section will be described with reference to FIGS. 14 and 15.

The controller may classify overlays for the weight candidate groups by unit region (S400), and the controller may generate a graph indicating the number of measurement regions for the overlay for each weight candidate group by unit region (S410).

Referring to FIG. 15, the graph may represent an overlay for a specific unit region. The horizontal axis in FIG. 15 may correspond to the overlay, and the vertical axis may correspond to the number of measurement regions. A center of the overlay for the first and second weights may be a target value TG. For example, the target value TG may be 0 or a value other than 0.

The weight candidate may include the first and second weights. The first and second weights may be weights determined as weight candidate groups in FIG. 11. However, the number of weights may not be limited thereto.

For example, when the first indices indicate dispersion of overlays for a single wafer, A, B, C, and D may correspond to different semiconductor process apparatuses. In another example, when the first indices indicate dispersion of overlays of wafers included in a lot, A to D may correspond to different wafers. However, one or more embodiments thereof is not limited thereto. In this case, at least one overlay among A to D may be a de-corrected overlay. For example, when the center of at least one overlay among A to D is different, the controller may further perform a process of controlling the center of overlay of A to D to be the same as the target value TG.

The limit section THR may correspond to an interval within the range of the limit point TH with the target value TG as the center. The controller may apply a limit section THR, which gradually decreases, to the graph (S420), thereby removing a weight beyond the limit section THR among the weight candidate groups (S430). A weight not beyond the limit section among the weight candidate groups may be determined as a final weight of the unit region (S440).

An overlay beyond the limit section THR may be determined as an outlier, and a weight including an overlay determined as an outlier may be removed. The limit section THR may be gradually decreased until one of the weight candidate groups does not include an outlier.

The first limit section THR1 may correspond to an interval within the range of the first limit point TH1 with the target value TG as the center. For example, the first limit section THR1 may correspond to a range from −first limit point −TH1 to +first limit point TH1.

The second limit section THR2 may be a section gradually reduced from the first limit section THR1. The second limit section THR2 may correspond to a section within the range of the second limit point TH2 with the target value TG as the center. For example, the second limit section THR2 may correspond to a range from −second limit point −TH2 to +second limit point TH2.

As one or more embodiments illustrated in FIG. 15, in B of the second limit section THR2, the first weight overlay may include an outlier, and the overlay to which the second weight is applied may not include an outlier. Among the weight candidate groups, the first weight beyond the limit section may be removed. For example, among the weight candidate groups, the second weight not beyond the limit section may be determined as a final weight of the unit region.

A method of determining the final weight of the unit region using the overlay range will be described with reference to FIGS. 16 and 17.

The controller may classify overlays for the weight candidate groups by unit region (S500). The controller may derive the overlay range for each weight candidate group by unit region (S510). The overlay range may be the difference between maximum and minimum values of the overlay for each weight candidate group. The controller may determine a weight having the narrowest overlay range among the weight candidate groups as a final weight of the unit region (S520).

The graph in one or more embodiments illustrated in FIG. 17 may represent an overlay for a specific unit region and may be similar to the example described with reference to FIG. 15 above. In one or more embodiments illustrated in FIG. 17, for the first weight of A, the minimum overlay range DRmin may be derived. For the second weight of A, the maximum overlay range DRmax may be derived. Since the first weight among the weight candidate groups has the smallest overlay range DRmin, the first weight may be determined as the final weight of the unit region.

The degree of deformation of the alignment mark may differ by wafer region. By determining the final weight by unit region, the difference in the degrees of deformation of the alignment marks by wafer region may be compensated for. For example, when the final position of the alignment mark is derived, the difference in the wafer regions in which the alignment marks are positioned may be offset. Accordingly, the final position of the alignment mark may be derived more accurately by unit region, such that an overlay of the wafer may be improved to be more efficient.

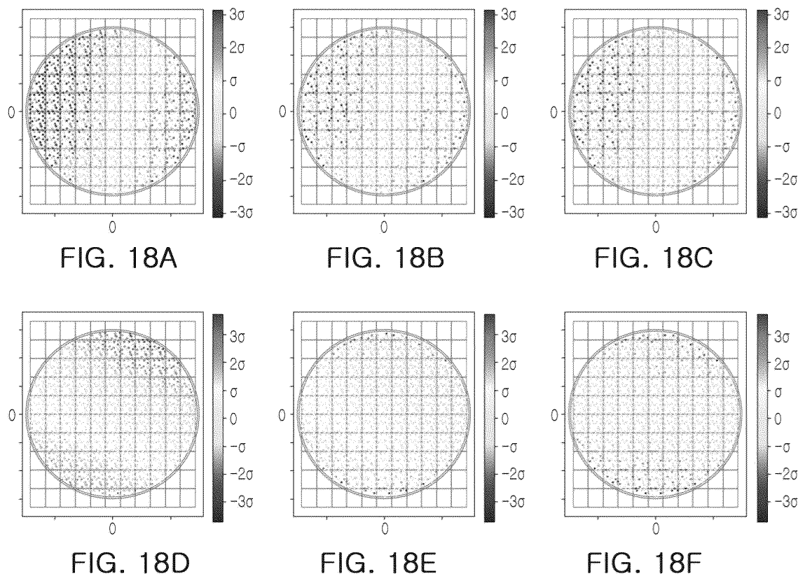

FIGS. 18A to 18F are diagrams illustrating overlay standard deviation derived from a wafer according to one or more embodiments.

A semiconductor process apparatus may measure an overlay at a plurality of measurement positions of a wafer. In this case, the semiconductor process apparatus may perform an exposure process based on the measured alignment positions using a weighted multiwavelength light, thereby generating overlay data. The semiconductor process apparatus may derive an overlay standard deviation of the plurality of measurement positions from the overlay data.

FIG. 18A to FIG. 18F may represent an overlay standard deviation between a plurality of measurement positions of a wafer. FIG. 18A to FIG. 18C may represent an overlay standard deviation of the X-axis of the overlay data. FIG. 18D to FIG. 18F may represent an overlay standard deviation of the Y-axis of the overlay data.

FIG. 18A and FIG. 18D may represent the overlay standard deviation of the semiconductor process apparatus in the one or more embodiments and a related example. The semiconductor process apparatus of the related example may measure overlay data in a single semiconductor process apparatus and may determine a weight by considering a single dispersion of overlay derived from the overlay data. The weight may be also applied to a plurality of unit regions of the wafer.

FIG. 18B and FIG. 18E may represent the overlay standard deviation of the semiconductor process apparatus in one or more embodiments. The semiconductor process apparatus in one or more embodiments may measure overlay data in a plurality of semiconductor process apparatuses and may determine a weight by considering multiple dispersion of overlays derived from the overlay data.

The weights applied to FIG. 18B and FIG. 18E may be applied equally to a plurality of unit regions of the wafer. The one or more embodiments may be similar to the examples described with reference to FIGS. 1 to 15 above. As compared to the weights applied in FIG. 18A and FIG. 18D, there may be a difference in determining the weights by measuring overlay data in the plurality of semiconductor process apparatuses and deriving a multi-dispersion of overlay from the overlay data.

FIG. 18C and FIG. 18F may represent the overlay standard deviation of the semiconductor process apparatus in one or more embodiments. The semiconductor process apparatus in one or more embodiments may determine the weights for the unit regions by measuring overlay data in the plurality of semiconductor process apparatuses and considering the multi-dispersion of overlay derived from the overlay data.

The weights applied in FIG. 18C and FIG. 18F may be applied differently to at least one of the plurality of unit regions of the wafer. The one or more embodiments may be similar to the examples described with reference to FIGS. 16 and 17 above. As compared to the weights applied in FIG. 18B and FIG. 18E, there may be a difference in determining and applying the weights by unit region.

As comparing FIG. 18A to FIG. 18C, dispersion of the overlay standard deviation for the X-axis may decrease from FIG. 18A to FIG. 18C. From FIG. 18A to FIG. 18C, the overlay standard deviation for the X-axis of the plurality of measurement positions may approach 0. For example, from FIG. 18A to FIG. 18C, the final X-axis position of the alignment mark derived from the multiwavelength light with the weight applied may be more accurate.

As comparing FIG. 18D to FIG. 18F, dispersion of the overlay standard deviation for the Y-axis may decrease from FIG. 18D to FIG. 18F. From FIG. 18D to FIG. 18F, the overlay standard deviation for the Y-axis of the plurality of measurement positions may approach 0. For example, from FIG. 18D to FIG. 18F, the final Y-axis position of the alignment mark derived from the weighted multiwavelength light may be more accurate.

For example, accuracy of the final position of the alignment mark may be improved from FIG. 18A to FIG. 18C and from FIG. 18D to FIG. 18F. As the error between the final position and the actual position of the alignment mark is reduced, dispersion of the overlay standard deviation may be reduced. For example, the overlay may be addressed and the yield of the semiconductor process may be improved.

At least one of the components, elements, modules or units (collectively “components” in this paragraph) represented by a block in the drawings may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

According to the aforementioned embodiments, by optimizing the weight applied to multiwavelength light used in the plurality of semiconductor process apparatus, the position of an alignment mark may be more accurately derived. In this case, the weight of the multiwavelength light may consider overlay data of the entire region of the wafer and/or unit region, and/or the position of the alignment mark. Accordingly, the dispersion of overlay may be addressed.

While embodiments have been illustrated and described above, it will be configured as apparent to those skilled in the art that modifications and variations could be made without departing from the scope of the present disclosure as defined by the appended claims and their equivalents.

What is claimed is:

1. A method of controlling a semiconductor process, the method comprising:
obtaining measurement data by measuring an alignment mark of a wafer based on multiwavelength light emitted by a plurality of semiconductor process apparatuses, and obtaining a final position of the alignment mark by applying a current weight to the measurement data;
performing a semiconductor process on the wafer by aligning a mask stage and a wafer stage based on the final position of the alignment mark;
measuring overlays of a plurality of measurement positions of the wafer by applying the current weight to the multiwavelength light, and generating overlay data by adding the measured overlays, with respect to the plurality of semiconductor process apparatuses;
obtaining first indices based on at least one of the measurement data and the overlay data, and obtaining second indices, different from the first indices, based on the overlay data;
generating machine learning models corresponding to the first indices and the second indices based on the current weight;
predicting the first indices corresponding to the plurality of semiconductor process apparatuses, respectively, for each of a plurality of weights configured to be applied to the multiwavelength light based on the machine learning models;
determining at least one weight among the plurality of weights as a weight candidate group based on the first indices for each of the plurality of semiconductor process apparatuses;
predicting second indices corresponding to the plurality of semiconductor process apparatuses, respectively, for the weight candidate group based on the machine learning models;
determining a weight from the weight candidate group as a final weight based on the second indices for the plurality of semiconductor process apparatuses, respectively; and
modifying the current weight to the final weight,
wherein the first indices comprises at least one of a distribution of overlay for the plurality of measurement positions of the wafer and an accuracy of the measurement data, and the second indices correspond to the distribution of overlay for the plurality of measurement positions of the wafer.

2. The method of claim 1, wherein the weight comprises a plurality of weight components corresponding to a plurality of beams of light included in the multiwavelength light, respectively.

3. The method of claim 2, wherein at least one of the plurality of weight components is different from remaining plurality of weight components.

4. The method of claim 2, wherein the plurality of weight components are positive, negative, or 0, and a sum of the plurality of weight components is 1.

5. The method of claim 1, wherein the first indices comprise at least one of an index corresponding to a dispersion of overlay of wafers included in a lot and an index corresponding to an accuracy of the final position of the alignment mark.

6. The method of claim 5, wherein the dispersion of overlay of wafers included in the lot is an average of values three times the overlay standard deviation for the plurality of measurement positions of wafers included in the lot.

7. The method of claim 1, wherein the second indices correspond to a dispersion of overlay for a single wafer.

8. The method of claim 7, wherein the second indices are a sum of an absolute value of an average of overlays of the plurality of measurement positions of the single wafer and a value three times the overlay standard deviation.

9. The method of claim 1, wherein the weight is applied to each of the plurality of semiconductor process apparatuses and an entire region of the wafer.

10. The method of claim 1, wherein the first indices and the second indices corresponding to each of the plurality of semiconductor process apparatuses are obtained from at least one wafer on which the semiconductor process is configured to be performed by an apparatus among the plurality of semiconductor process apparatuses.

11. A method of controlling a semiconductor process, the method comprising:
obtaining measurement data by measuring an alignment mark of a wafer based on multiwavelength light emitted by a plurality of semiconductor process apparatuses, and obtaining a final position of the alignment mark by applying a current weight to the measurement data;
aligning a mask stage and a wafer stage based on the final position of the alignment mark and performing a semiconductor process on the wafer;
measuring overlays of a plurality of measurement positions of the wafer by applying the current weight to the multiwavelength light, and generating overlay data by adding the measured overlays, with respect to the plurality of semiconductor process apparatuses;
obtaining first indices based on at least one of the measurement data and the overlay data, and obtaining second indices, different from the first indices, based on the overlay data;
obtaining first average indices, an average of the first indices, and second average indices, an average of the second indices, for each of the plurality of semiconductor process apparatuses based on the first indices and the second indices corresponding to the current weight;
generating machine learning models corresponding to the first indices and the second indices based on the current weight;
predicting first average indices corresponding to the plurality of semiconductor process apparatuses, respectively, for each of a plurality of weights configured to be applied to the multiwavelength light based on the machine learning models;
determining at least one weight in which a first average index is outside of and less than a predetermined range of index or the same as the current weight among the plurality of weights as a weight candidate group;
predicting second average indices for the plurality of semiconductor process apparatuses, respectively, for the weight candidate group based on the machine learning models;
determining a weight in which a second average index is outside of the predetermined range of index and has the smallest value in the weight candidate group as a final weight; and
modifying the current weight to the final weight.

12. The method of claim 11, wherein the weight comprises a plurality of weight components corresponding to a plurality of beams of light included in the multiwavelength light, respectively.

13. The method of claim 11, wherein the first indices comprise at least one of an index corresponding to a dispersion of overlay for the single wafer and an index corresponding to an accuracy of the measurement data.

14. The method of claim 11, wherein the second indices correspond to dispersion of overlay of wafers included in a lot.

15. The method of claim 11, wherein the first indices and the second indices corresponding to each of the plurality of semiconductor process apparatuses are obtained from at least one of the wafers on which the semiconductor process is configured to be performed by an apparatus among the plurality of semiconductor process apparatuses.

16. A method of controlling a semiconductor process, the method comprising:
obtaining measurement data by measuring an alignment mark of a wafer based on multiwavelength light in a plurality of semiconductor process apparatuses, and obtaining a final position of the alignment mark by applying a current weight to the measurement data;
aligning a mask stage and a wafer stage based on the final position of the alignment mark and performing a semiconductor process on each of a plurality of unit regions of the wafer;
measuring overlays of a plurality of measurement positions of the wafer by applying the current weight to the multiwavelength light, and generating overlay data by adding the measured overlays, with respect to the plurality of semiconductor process apparatuses;
obtaining first indices corresponding to a distribution of overlays for the plurality of measurement positions of the wafer based on the overlay data;
generating machine learning models corresponding to the first indices and an overlay based on the current weight;
predicting first indices for the plurality of semiconductor process apparatuses, respectively, for each of a plurality of weights configured to be applied to the multiwavelength light based on the machine learning models;
determining at least one weight among the plurality of weights as a weight candidate group based on the first indices for each of the plurality of semiconductor process apparatuses;
predicting the overlay corresponding to the weight candidate group based on the machine learning models;
classifying the overlays for the weight candidate group by unit region;
determining a weight from the weight candidate group that is outside of and less than a predetermined range of overlay as a final weight with respect to each of the plurality of unit regions; and
modifying the current weight to the final weight with respect to the unit region.

17. The method of claim 16, wherein the determining as the final weight further comprises:
generating a graph corresponding to a number of measurement regions for the overlay for each unit region corresponding to each weight candidate group; and
removing weights outside of a limit section among weight candidate groups by applying the limit section, which gradually decreases, and repeatedly performing an operation of adjusting the limit section until the final weight is obtained.

18. The method of claim 17, wherein the first indices correspond to a dispersion of overlay for a single wafer, and the graph is generated for each of the weight candidate groups for each of the single wafer.

19. The method of claim 17, wherein the first indices correspond to a dispersion of overlay of wafers included in a lot, and the graph is generated for each of the weight candidate groups for each of the lot.

20. The method of claim 16, wherein the determining as the final weight further comprises:
obtaining an overlay range for each of the weight candidate groups for each of the plurality of unit regions; and
obtaining a weight having the smallest overlay range among the weight candidate groups as the final weight.
